(19) United States
(12) Patent Application Publication
(10) Pub. No.: US 2022/0231636 A1
(43) Pub. Date: Jul. 21, 2022

(54) NOVEL PHOTOVOLTAIC PANEL LAYOUT AND INTERCONNECTION SCHEME TO ENABLE LOW VOLTAGE AND HIGH OUTPUT POWER IN AN ENERGY GENERATING PHOTOVOLTAIC SYSTEM

(71) Applicant: EvoluSun, Inc., San Jose, CA (US)

(72) Inventors: Shashwat Kumaria, San Jose, CA (US); Rohini Raghunathan, Fremont, CA (US); Miguel Martinho Lopes Praca, Cascais (PT); Vivek Phanse, San Mateo, CA (US)

(21) Appl. No.: 17/151,068

(22) Filed: Jan. 15, 2021

(51) Int. Cl. H02S 40/36; H02S 20/26

(52) U.S. Cl. CPC H02S 40/36; H02S 20/26

(57) ABSTRACT

A solar system, arranged in one or more sub-systems, consists of solar panels. The solar panels are configured into a plurality of solar panel strings, using interconnect wires, wherein a solar panel string comprises at least two of the solar panels electrically connected in a serial manner. The solar panels of a first of the solar panel strings are arranged between at least one of the solar panels of a second of the solar panel strings, and the interconnect wires, for each of the solar panel strings, form only a single path between the top and the bottom of the sub-system. This wiring configuration has application to house wires in a solar awning with limited space to house solar panel interconnect wires.

### FIELD OF THE INVENTION

This application is related to the field of solar photovoltaic power generating systems. More specifically, this application relates to novel layout and interconnection schemes of photovoltaic panels within a solar system to optimize operation of the solar system.

### BACKGROUND

The following description includes information that may be useful in understanding the disclosure set forth herein. It is not an admission that any of the information provided herein is prior art or relevant to the presently claimed invention, or that any publication specifically or implicitly referenced is prior art.

All publications herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

Many buildings, vehicles (such as recreational vehicles), pergolas, and boats use visors, awnings, shade screens, canopies or blinds to protect against solar radiation, provide shade and keep buildings or vehicles cool.

Incorporating solar generation capabilities on these shade-providing structures is advantageous because it provides the dual benefit of blocking sunlight while simultaneously using that impinging sunlight to generate electrical power.

As an example, vehicles such as RVs, use awnings for shade. Users of RVs also have a strong need for clean and silent off-grid power that enables the use of RVs in remote locations for extended periods of time.

Traditionally, solar panels are installed on roofs of RVs, but roofs typically have very limited available area for panel installation due to the presence of an air conditioner, air conditioner vents, bathroom vents, refrigerator vent, bathroom skylights, etc. at different locations on the roof.

This lack of available roof area greatly limits the number of solar panels that can be installed on a given roof, and hence the total amount of power generated by the installed solar system.

The present disclosure sets forth embodiments of a solar awning, such as for use in an RV, that overcome the above-mentioned constraints.

### BRIEF DESCRIPTION OF THE DRAWINGS

FIG. 1 illustrates one embodiment of a layout of a solar system and the sub-systems within the solar system.

FIG. 2 illustrates one embodiment of a solar sub-system with an alternating layout of adjacent solar panels.

FIG. 3 illustrates another embodiment of a solar sub-system layout with three solar panel strings.

FIG. 4 illustrates yet another embodiment of a sub-system layout within the solar system.

FIG. 5 illustrates one embodiment of a sub-set of solar panels in one sub-system interconnected to solar panels in an adjacent sub-system to form an electrical string.

FIG. 6 illustrates one embodiment of a solar awning system for which embodiments of the solar system disclosed herein may be incorporated.

FIG. 7 illustrates an application for the solar panel layout and interconnects scheme disclosed herein.

### DETAILED DESCRIPTION

A solar system integrated into structures such as awnings, shade screens, and canopies is in relatively close proximity to human contact. Hence, there is a need to maintain low (safe) voltage output from a solar awning. But there is also a need to maximize total power of the awning which effectively results in an increase in the total number of solar panels.

Increase in the total number of panels results in a correspondingly increase of the number of panels that are electrically connected in series in a given electrical ‘string’ of panels, hence increasing the string voltage.

Both of the above-mentioned needs for low voltage and more power can only be met by reducing the number of panels electrically connected in series in a given electrical string, and correspondingly increasing the number of electrical strings in the awning.

However, an increase in the number of strings results in a corresponding increase in number of wires in the solar system.

An increase in the number of wires requires more space for wire management within the awning, but there is a strong constraint on the amount of available space in the awning due to the highly compact and retracting nature of the awning; thereby severely constraining the number of wires that can be accommodated in the design. For example, such awnings are described in U.S. Pat. No. 10,560,050, entitled “Innovative Energy Generating Photovoltaic Awning”, and U.S. patent application Ser. No. 16/932,751, entitled “Energy Generating Photovoltaic Awning with Scissor Mechanism and Tilting Photovoltaic Panels”, both assigned to the applicant of the present application, EvoluSun, Inc., and are both expressly incorporated herein by reference in their entirety.

The embodiments disclosed herein overcome the above constraints; and results in a low voltage without sacrificing the total output power of the awning.

In some embodiments, the awning solar system is comprised of a plurality of solar sub-systems which in turn comprise of a plurality of solar panels.

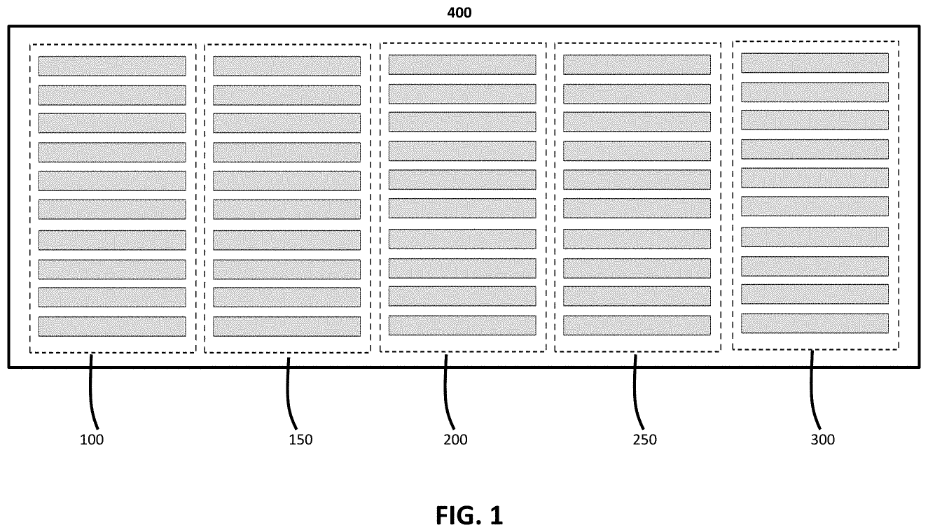

In some embodiments, solar panels are grouped into mechanical modular sub-systems such that each sub-system is comprised of a plurality of solar panels, and sub-systems are placed next to one another. For the embodiment shown in FIG. 1, solar system (400) consists of subsystems 100, 150, 200, 250 and 300. Although FIG. 1 illustrates a solar system with 5 subsystems, any number of subsystems may be incorporated into a system without deviating from the spirit or scope of the invention.

Each sub-system is further comprised of two or more solar strings; and each string consists of a plurality of solar panels connected serially to form an electrical circuit.

In one embodiment, the orientation of the solar panels of a given string within a sub-system is such that the electrical wiring of all the panels within one string terminates on one side (left or right); and the wiring of all the panels within the second string terminates on the opposite side with respect to the first string (right or left).

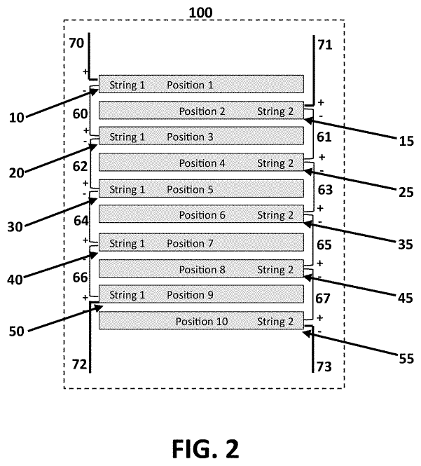

FIG. 2 illustrates one embodiment of a sub-system configured with two solar panel strings. For this embodiment, the solar panels for a first solar panel string are interdigitated between the solar panels of a second solar panel string. Specifically, solar panel string 1 consists of a serial connection to electrically couple solar panels 10, 20, 30, 40 and 50, whereas solar panel string 2 consists of a serial connection to electrically couple solar panels 15, 25, 35, 45 and 55. Also as shown in FIG. 2, the solar panel strings are configured with a plurality of interconnect wires. For example, solar panel string 1 consists of interconnect wires 70, 60, 62, 64, 66, and solar panel string 2 consists of interconnect wires 71, 61, 63, 65, 67 and 73.

For the embodiment shown in FIG. 2, in order to conserve space for housing the interconnect wires, each solar power string constitutes only a single path of interconnect wires between the top and the bottom of the sub-system. Specifically, solar panel string 1 is routed between its origin, interconnect wire 70, and its termination, interconnect wire 72, entirely on the left-hand side of the subsystem 100. Similarly, solar panel string 2 is routed between its origin, at interconnect wire 71, and its termination, at interconnect wire 73, as a single path on the right-hand side of sub-system 100.

Each solar cell typically produces an open-circuit voltage of 0.70V. Each solar panel in the solar system disclosed herein, may consist of 10 solar cells serially connected to produce a voltage of 7.0V. For this example, solar panel string 1, shown in FIG. 2, comprises of five solar panels serially connected to produce a voltage of 35V. Similarly, solar panel string 2 in the sub-system 100 shown in FIG. 2 also produces 35V.

In some embodiments, the spacing between the solar panels within a solar panel string is such that each solar panel is separated by one panel spacing from the next solar panel within the same string (See the embodiment of FIG. 2). The solar panels in the second solar panel string are similarly connected such that each panel is separated by one panel spacing from the next panel within the same string (See the embodiment of FIG. 2).

For the embodiment of FIG. 2, this results in a layout wherein the solar panels in one string are placed in positions 1, 3, 5, 7 and 9 within the sub-system; and solar panels within the second solar panel string are placed in positions 2, 4, 6, 8, and 10. Hence, the solar panels in one solar power string are effectively interdigitated with the solar panels in the second solar power string.

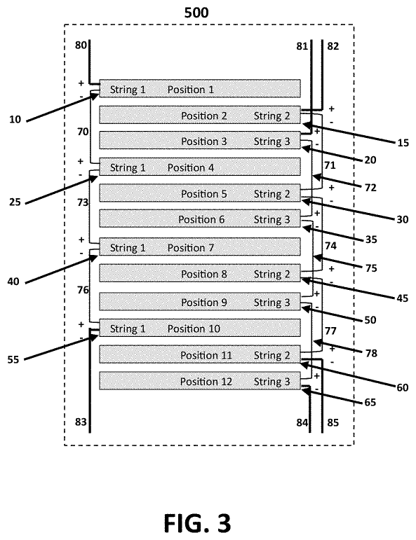

In other embodiments, there are more than two strings in one sub-system. Spacing between panels in a given circuit is thus increased to two panel spacings; and three strings are now interdigitated (See the embodiment of FIG. 3)

FIG. 3 illustrates one embodiment of a solar subsystem that incorporates three solar panel strings. As shown, sub-system 500 incorporates 12 solar panels (i.e., 12 positions for placement of solar panels), configured to form three solar power strings (i.e., solar panel strings 1, 2 and 3). Specifically, solar panel string 1 consists of solar panels at position 1, 4, 7 and 10, connected by interconnect wires 80 (originating), 70, 73, 76 and 83 (terminating). The interconnect wires that form solar panel string 1 form only a single path, along the left-hand side of the sub-system, between the top and the bottom of the sub-system 500.

For the embodiment shown in FIG. 3, solar panel strings 2 and 3 are routed on the right-hand side of the subsystem 500. Specifically, solar panel string 2 consists of solar panels in positions 2, 5, 8 and 11, connected by interconnect wires 82 (originating), 71, 74, 77 and 85 (terminating). Solar panel string 3 forms a solar panel string from solar panels at positions 3, 6, 9 and 12, connected by interconnect wires 81 (originating), 72, 75, 78 and 84 (terminating). Both solar panel strings 2 and 3 form only a single path, along the right-hand side of the sub-system 500, between the top and the bottom of the sub-system 500.

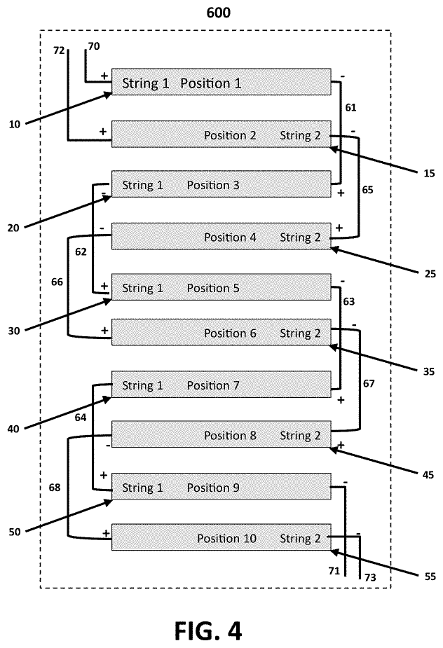

In yet other embodiments, solar panels have wires that originate and terminate at opposite ends, and the solar panels are arranged in an interdigitated layout within a sub-system. FIG. 4 illustrates one embodiment of a sub-system 600 for which the interconnect wires of two solar panel strings originate and terminate at the same sites. Specifically, solar panel string 1 consists of serially connected solar panels located at positions 1, 3, 5, 7 and 9, and are interconnected by interconnect wires 70 (originating), 61, 62, 63, 64, and 71 (terminating). Solar panel string 2 has a similar configuration, such that solar panel string 2 consists of solar panels at located positions 2, 4, 6, 8 and 10, and is interconnected by interconnect wires 72 (originating), 65, 66, 67, 68 and 73 (terminating). As such, for this embodiment, both solar panel strings 1 and 2 originate and terminate on opposites sides (i.e., solar strings 1 and 2 originate on the left-hand side of sub-system 600, whereas solar panel strings 2 and 3 terminate on the right-hand side of sub-system 600).

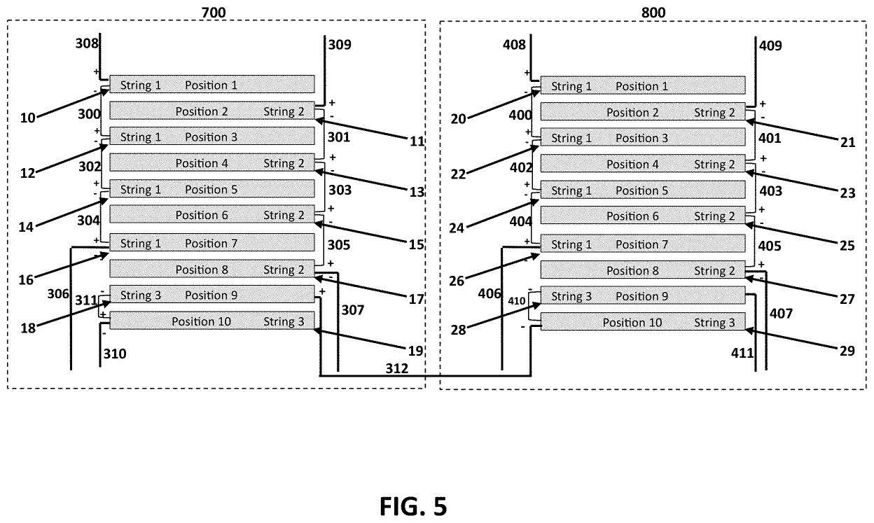

In another embodiment, some panels are electrically connected in series across sub-systems to create a solar string (FIG. 5).

FIG. 5 illustrates an embodiment for interconnection of solar panels across more than one sub-system. In this exemplary embodiment, two sub-systems (700 and 800) are shown. In sub-system 700, solar panels 10, 12, 14, and 16 are electrically connected in series to form solar panel string 1; and solar panels 11, 13, 15, 45, and 17 are electrically connected in series to form the solar panel string 2. In sub-system 800, solar panels 20, 22, 24, and 26, are electrically connected in series to form solar panel string 1; and solar panels 21, 23, 25, and 27 are electrically connected in series to form solar panel string 2. Solar panels 18 and 19 in sub-system 700 are electrically connected in series with solar panels 28 and 29 in sub-system 800 to form solar panel string 3. Further, in sub-system 700, wire 300 connects panels 10 and 12, interconnect wire 302 connects solar panels 12 and 14, interconnect wire 304 connects solar panels 14 and 16, interconnect wire 301 connects solar panels 11 and 13, interconnect wire 303 connects solar panels 13 and 15; and interconnect wire 305 connects solar panels 15 and 17.

In sub-system 800, interconnect wire 400 connects solar panels 20 and 22, interconnect wire 402 connects solar panels 32 and 34, interconnect wire 404 connects solar panels 24 and 26, interconnect wire 401 connects solar panels 21 and 23, interconnect wire 403 connects solar panels 23 and 25; and interconnect wire 405 connects solar panels 25 and 27. In solar panel string 3, wire 311 connects solar panels 18 and 19, wire 312 connects solar panels 19 and 29, and wire 410 connects panels 29 and 28.

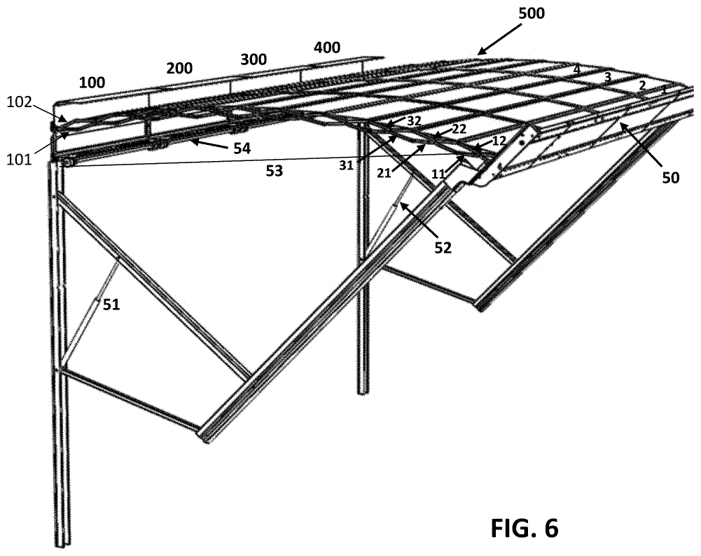

The embodiments disclosed herein have applications for use in a solar power awning system. FIG. 6 illustrates one embodiment of a solar awning system in a deployed state. The solar awning (500) consists of enclosures with solar panels stacked inside it (100, 200, 300 and 400) mounted adjacent to each other on a wall. Each stack of solar panels consists of several modules (1, 2, 3, 4, etc.). The solar panels (1, 2, 3 and 4) are coupled, directly or indirectly, to each other through scissor links (11, 12, 21, 22, 31 and 32), respectively, on one end and another set of identical links in the other end (not shown).

In this embodiment, the system is actuated using an air strut (51, 52), or similar mechanism, that pushes the lead arm (50) forward. The movement of the lead arm (50) is controlled using a cable (53) that is attached to it and is wound on a roller tube (54) on the other end. The roller tube (54) in this embodiment is located at the base of the awning and is rotated using a motor mounted next to it. As the roller tube (54) is rotated in one direction, the cable (53) gets wound on it pulling the lead arm (50) closer to the base and thereby retracing the awning. Conversely, when the roller tube (54) is rotated in the other direction the cable (53) is unwound on it, allowing the lead arm (50) to be pushed further by the air struts (51, 52), thereby expanding the awning.

While it is contemplated that the photovoltaic awning system is deployed and retracted generally via an electrical motor, the photovoltaic awning system is also designed to operate by manually operating the motive element (e.g., turning a crank, pulling a line, extending a pole, etc.) in a default mode, in case the electrical actuation fails. In other embodiments, it is conceivable that the photovoltaic awning system may be operated via pneumatic force, hydraulic force, mechanical force, electromagnetic force, or gravitational force.

As the lead arm moves back and forth, it pulls the last scissor link attached to it which, in turn, pulls along with it all the interconnect scissor links and solar panels. Additionally, since the last scissor links from all stacks of solar panels (100, 200, 300, 400) are connected to the same lead arm (50) it enables synchronous deployment of all the solar panels as the lead arm (50) moves back and forth.

The first scissor link in every stack of solar panel (11, 12 for example) is connected to lead arm (50), and the last link in every stack of solar panel (101,102 for example) is connected to the enclosure or base (100 and 400, for example), mounted on the wall.

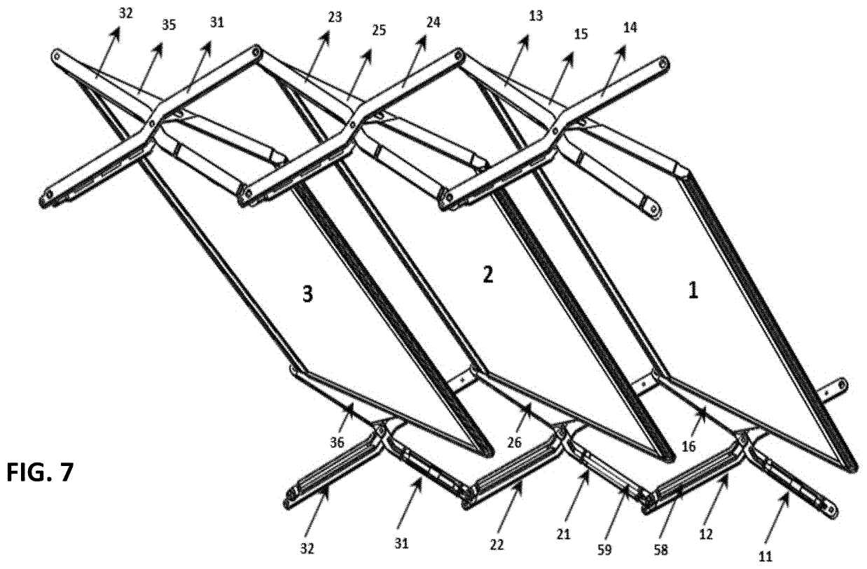

FIG. 7 illustrates an application for the solar panel layout and interconnects scheme disclosed herein. This embodiment includes a plurality of angled side frames (25 and 26 for solar panel 2, 15 and 16 for solar panel 1, 35 and 36 for solar panel 3). As illustrated in FIG. 7, the angled side frames (25 and 26, 15 and 16, and 35 and 36), located at the two ends of the solar panels (2, 1 and 3, respectively), are directly attached to scissor links (21 and 23 for solar panel 2, 13 and 11 for solar panel 1, 32 and 31 for solar panel 3) keeping the solar panels (2, 1 and 3) at a fixed offset to the links (21 and 23, 13 and 11, 32 and 31). Each of these scissor links, on which the solar panels are attached, are then pivotally connected, at its center, top and bottom ends, to three other scissor links on which there are no solar panels attached as shown in FIG. 7. For example, scissor link 21 is connected pivotally to scissor link 22 at its center, and scissor links 32 and 12 on its top and bottom. The scissor links 32 and 12 do not have any modules attached to them. Each of the end scissor links 32 and 12 are in turn pivotally connected at its center to scissor links 31 and 11 on which solar panels are attached. Scissor links 31 and 11 are in turn connect to scissor link 22 on its two ends making this a completely interconnected system of three panels that are interconnected to each other via scissor links and can be actuated using the scissor links. The solar panels (2, 1 and 3) attached on scissor links (11, 21 and 31), respectively, are adjacent to each other and move in synchronization and parallel to one another.

FIG. 7 also illustrates one embodiment for electrically interconnecting the solar modules. As illustrated in FIG. 7, the electrical interconnection between the solar modules (1, 2) is routed through channels (58, 59) attached on the scissor links (12, 21). This routing always enables the wiring between two modules to stay at fixed length preventing slack when closed. The scissor link in this embodiment is designed to house a connector between the modules so that the modules can be disconnected and replaced easily in the field.

The panel layout and interconnect schemes disclosed herein support mounting of wires in a solar awning that has limited space since the interconnect wires form only a single path across the solar panels (1, 2 and 3). For example, for the embodiment shown in FIG. 7, the panel layout and interconnect schemes enable mounting interconnect wires through channels (58, 59) on the scissor links (12, 21).

Although the present invention has been described in terms of specific exemplary embodiments, it will be appreciated that various modifications and alterations might be made by those skilled in the art without departing from the spirit and scope of the invention.

What is claimed is:

1. A solar system comprising:
a plurality of solar panels, wherein a solar panel comprises a plurality of solar cells;
at least one sub-system that comprises a plurality of the solar panels arranged adjacently and substantially parallel to a top and a bottom of the sub-system;
a plurality of solar panel strings, wherein a solar panel string comprises at least two of the solar panels electrically connected in a serial manner;
a plurality of interconnect wires for electrically connecting the solar panels to create at least two of the solar panel strings,
wherein the solar panels of a first of the solar panel strings are arranged between at least one of the solar panels of a second of the solar panel strings; and
wherein the interconnect wires, for each of the solar panel strings, create only a single path between the top and the bottom of the sub-system.

2. The solar system as set forth in claim 1, wherein the solar panel strings are configured to generate a voltage not to exceed a voltage specification.

3. The solar system as set forth in claim 1, wherein at least one of the solar panel strings produce a voltage of approximately 35 volts.

4. The solar system as set forth in claim 1, wherein the sub-system comprises two solar panel strings for at least one of the sub-systems.

5. The solar system as set forth in claim 4, wherein the interconnect wires for a first of the solar panel strings begin and terminate on one side of the sub-system, and the interconnect wires for a second of the solar panel strings begin and terminate on the opposite side of the sub-system from the first solar panel string.

6. The solar system as set forth in claim 4, wherein the interconnect wires for the two solar panel strings begin and terminate on opposite sides of the subsystem.

7. The solar system as set forth in claim 1, wherein at least one sub-system comprises three solar panel strings.

8. The solar system as set forth in claim 7, wherein the interconnect wires for a first of the solar panel strings begin and terminate on one side of the sub-system, and the interconnect wires for a second and third of the solar panel strings begin and terminate on an opposite side of the sub-system from the first solar panel string.

9. The solar system as set forth in claim 7, further comprising a plurality of sub-systems, and wherein the solar system comprises at least three solar panel strings connecting the solar panels across more than one sub-system.

10. A method for assembling at least one sub-system in a solar system that comprises a plurality of the solar panels arranged adjacently and substantially parallel to a top and a bottom of the sub-system, comprising:
using a plurality of interconnect wires to electrically connect, in a serial manner, a plurality of the solar panels to form at least two solar panel strings;
wherein the solar panels of a first of the solar panel strings are arranged between at least one of the solar panels of a second of the solar panel strings; and
wherein the interconnect wires, for each of the solar panel strings, create only a single path between the top and the bottom of the sub-system.

11. The method as set forth in claim 10, further comprising configuring the solar panel strings to generate a voltage not to exceed a voltage specification.

12. The method as set forth in claim 10, further comprising configuring the solar panel strings to produce a voltage of approximately 35 volts.

13. The method as set forth in claim 10, wherein the sub-system comprises two solar panel strings for at least one of the sub-systems.

14. The method as set forth in claim 13, wherein the interconnect wires for a first of the solar panel strings begin and terminate on one side of the sub-system, and the interconnect wires for a second of the solar panel strings begin and terminate on the opposite side of the sub-system from the first solar panel string.

15. The method as set forth in claim 13, wherein the interconnect wires for the two solar panel strings begin and terminate on opposite sides of the subsystem.

16. The method as set forth in claim 10, wherein at least one sub-system comprises three solar panel strings.

17. The method as set forth in claim 16, wherein the interconnect wires for a first of the solar panel strings begin and terminate on one side of the sub-system, and the interconnect wires for a second and third of the solar panel strings begin and terminate on an opposite side of the sub-system from the first solar panel string.

18. The method as set forth in claim 16, further comprising a plurality of sub-systems, and wherein the solar system comprises at least three solar panel strings connecting the solar panels across more than one sub-system.
